(19) United States
(12) Patent Application Publication
(10) Pub. No.: US 2016/0093550 A1
(43) Pub. Date: Mar. 31, 2016

(54) ELECTRONIC DEVICE HAVING A HEAT RADIATING UNIT

(71) Applicant: KABUSHIKI KAISHA TOSHIBA, Tokyo (JP)

(72) Inventors: Kengo KUMAGAI, Yokohama Kanagawa (JP); Hitoshi YAGISAWA, Yokohama Kanagawa (JP)

(21) Appl. No.: 14/636,050

(22) Filed: Mar. 2, 2015

(30) Foreign Application Priority Data
Sep. 30, 2014 (JP) 2014-202641

(51) Int. Cl. H01L 23/367; H05K 7/20; H01L 23/498; H01L 25/18; H01L 23/04

(52) U.S. Cl. CPC H01L 23/3675; H01L 25/18; H01L 23/04; H01L 23/49838; H05K 7/20963; H05K 7/2039

(57) ABSTRACT

An electronic device includes a first electronic unit, a second electronic unit disposed adjacent to the first electronic unit, and a heat radiating unit. The second electronic unit has a first portion and a second portion that is closer to the first electronic unit than the first portion. The heat radiating unit is disposed such that heat generated in the second portion of the second electronic unit is directed towards the first portion of the second electronic unit and from the first portion towards an outside of the electronic device.

### CROSS-REFERENCE TO RELATED APPLICATION

This application is based upon and claims the benefit of priority from Japanese Patent Application No. 2014-202641, filed Sep. 30, 2014, the entire contents of which are incorporated herein by reference.

### FIELD

Embodiments described herein relate generally to an electronic device having a heat radiating unit.

### BACKGROUND

An electronic device, such as a semiconductor device, has a controller and a semiconductor memory unit.

### DESCRIPTION OF THE DRAWINGS

FIG. 1 is a block diagram illustrating a semiconductor device according to a first embodiment.

FIG. 2 is a plan view of the semiconductor device illustrating arrangement of components therein.

FIG. 3 is a plan view of the semiconductor device illustrated in detail.

FIG. 4 is a cross-sectional view of a drive control circuit mounted on the semiconductor device.

FIG. 5 is a perspective view of the drive control circuit with an emphasis on a heat conductive sheet laminated on the drive control circuit.

FIGS. 6 and 7 are a cross-sectional view of the drive control circuit illustrating a heat radiation process

FIG. 8 is a cross-sectional view of a drive control circuit according to a first modification example of the first embodiment.

FIG. 9 is a plan view of a heat conductive sheet according to a second modification example of the first embodiment.

FIG. 10 is a plan view of the heat conductive sheet according to a third modification example of the first embodiment.

FIG. 11 is a cross-sectional view of the heat conductive sheet according to a fourth modification example of the first embodiment.

FIG. 12 is a cross-sectional view of the heat conductive sheet according to another fourth modification example of the first embodiment.

FIG. 13 is a perspective view of a semiconductor device according to a second embodiment.

FIG. 14 is a cross-sectional view of the semiconductor device according to a second embodiment.

FIG. 15 is a perspective view of a semiconductor device according to a third embodiment.

FIG. 16 is a cross-sectional view of the semiconductor device according to the third embodiment.

FIG. 17 is a cross-sectional view of a drive control circuit according to a fourth embodiment.

FIG. 18 is a cross-sectional view of the drive control circuit according to the fourth embodiment.

FIG. 19 is a perspective cross-sectional view of a tablet portable computer having a semiconductor device according to a sixth embodiment.

FIG. 20 is perspective cross-sectional view of a tablet portable computer having a semiconductor device according to a seventh embodiment.

### DETAILED DESCRIPTION

It is desirable that an electronic device, such as a semiconductor device, efficiently radiate heat generated therein. One or more of exemplary embodiments is directed to improve heat radiation efficiency of such an electronic device.

In general, according to one embodiment, an electronic device includes a first electronic unit, a second electronic unit disposed adjacent to the first electronic unit, and a heat radiating unit. The second electronic unit has a first portion and a second portion that is closer to the first electronic unit than the first portion. The heat radiating unit is disposed such that heat generated in the second portion of the second electronic unit is directed towards the first portion of the second electronic unit and from the first portion towards an outside of the electronic device.

Hereinafter, embodiments are explained with reference to drawings.

In this disclosure, with respect to some structural elements, a plurality of expressions is used for expressing each structural element. However, these expressions are merely examples, and each of the above-described structural elements may be expressed using other expressions. Further, the structural elements which are not expressed using a plurality of expressions may be also expressed using different expressions.

The drawings are schematic views and, hence, the relationship between thicknesses and planar sizes, a ratio of thicknesses of the respective layers and the like are not always equal to those of an actual semiconductor device. Further, the relationship or ratios of sizes of the parts may differ depending on drawings.

### First Embodiment

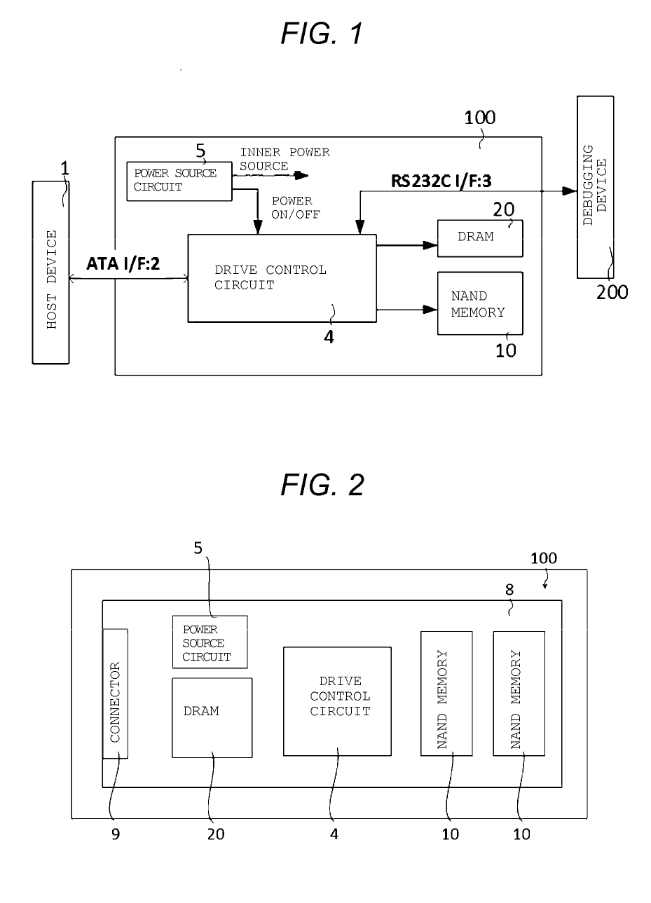

FIG. 1 is a block diagram illustrating an example of a semiconductor device 100 according to a first embodiment. FIG. 2 is a plan view of the semiconductor device 100 according to the first embodiment. The semiconductor device 100 is one example of “semiconductor module” or “semiconductor storage device.” The semiconductor device 100 according to this embodiment is an SSD (Solid State Drive), for example. However, the semiconductor device 100 according to this embodiment is not limited to the SSD, and may include a non-volatile semiconductor storage device such as an SD memory card and a controller which controls the non-volatile semiconductor storage device, for example.

As illustrated in FIG. 1, the semiconductor device 100 according to this embodiment is connected to a portable computer, which is one example of electronic equipment, or a host device (hereinafter referred to as “host”) 1 such as a CPU core, through a memory connection interface such as an interface 2 which conforms to an SATA (Serial Advanced Technology Attachment) or a PCIe (Peripheral Component Interconnect Express). Accordingly, the semiconductor device 100 functions as an external memory of the host 1. The interface 2 may conform to other standards.

The semiconductor device 100 receives power supplied from the host device 1 through the interface 2. The host 1 is, for example, a device which includes a CPU of the above-described computer or a CPU of an imaging device such as a still camera or a video camera. Further, the semiconductor device 100 may transmit/receive data to/from a debugging device 200 through a communication interface 3 such as an RS232C interface (RS232C I/F). The semiconductor device 100 may be used as a storage device of a server in which a plurality of other semiconductor devices 100 are mounted or a storage device of electronic equipment such as a tablet terminal, for example.

As illustrated in FIG. 2, the semiconductor device 100 includes: a NAND-type flash memory (hereinafter referred to as “NAND memory”) 10 which configures a non-volatile semiconductor memory element: a drive control circuit 4 which configures a controller: a DRAM (Dynamic Random Access Memory) 20 which is a volatile semiconductor memory element capable of performing a speed storage operation at a speed higher than the NAND memory 10; and a power source circuit 5.

The NAND memory 10 and the drive control circuit 4 of this embodiment are mounted on the semiconductor device 100 as a semiconductor package, which is an electronic module. For example, a semiconductor package of the NAND memory 10 is an SiP (System in Package) type module, and a plurality of semiconductor chips are sealed in one package. The drive control circuit 4 controls operation of the NAND memory 10. That is, the drive control circuit 4 controls writing of data into the plurality of NAND memories 10, reading of data from these NAND memories 10, and erasing of data in these NAND memories 10.

The power source circuit 5 generates a plurality of different internal DC power source voltages using an external DC power supplied from a power source circuit on a host 1 side, and supplies these internal DC power source voltages to respective circuits of the semiconductor device 100. The power source circuit 5 generates a power-on reset signal upon detection of rising of the external power source, and supplies the signal to the drive control circuit 4.

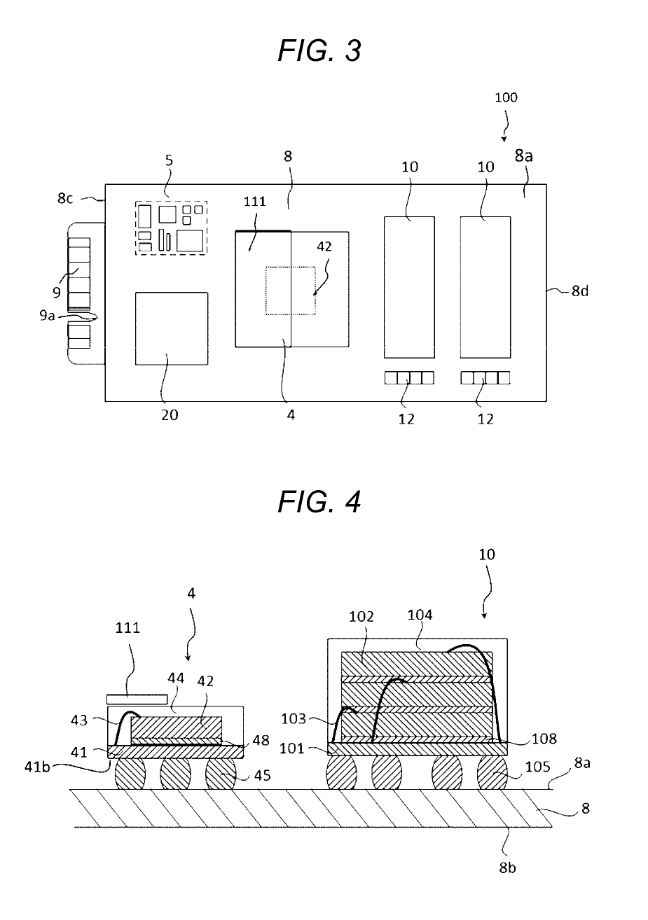

Next, mounting configuration of the semiconductor device 100 according to this embodiment is explained with reference to FIG. 3 and FIG. 4. FIG. 3 is a plan view of the semiconductor device 100 according to this embodiment. FIG. 4 is a cross sectional view of a semiconductor package including the drive control circuit 4 the NAND memory 10, and a circuit board 8 according to this embodiment.

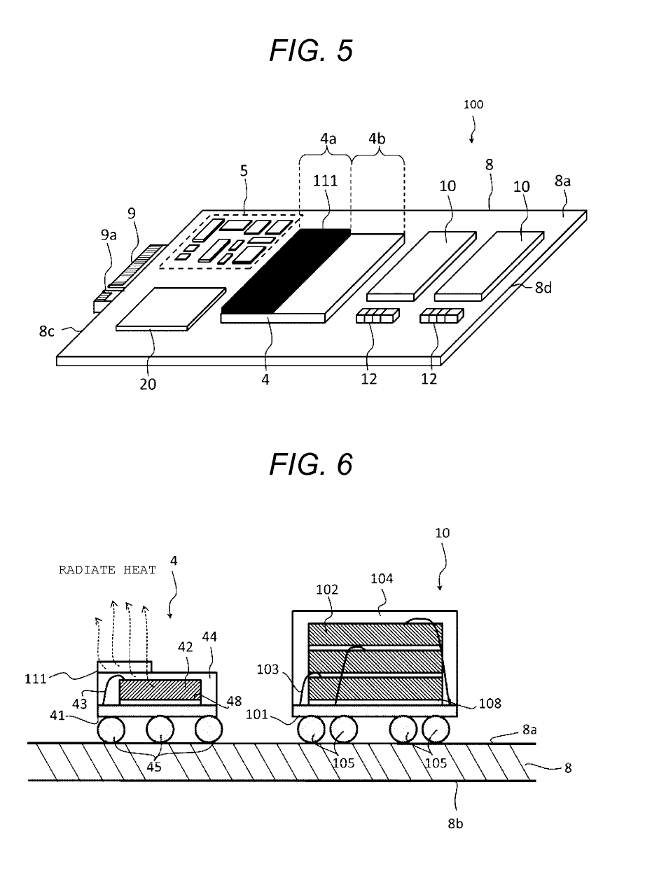

As illustrated in FIG. 3, in the semiconductor device 100 according to this embodiment, the power source circuit 5, the DRAM 20, the drive control circuit 4, the NAND memories 10, and resistance elements 12 are mounted on the circuit board 8 on which a wiring pattern (not shown in the drawing) is formed. A heat conductive sheet 111, which is one example of a radiator, is formed on a surface of the drive control circuit 4. Details of this heat conductive sheet 111 are explained below with reference to FIG. 5 and the subsequent drawings.

The circuit board 8 is a printed circuit board made of a material such as a glass epoxy resin, for example, and has an approximately rectangular shape as shown in FIG. 3. The circuit board 8 has a first surface 8a and a second surface 8b opposite to the first surface 8a. The first surface 8a is a parts mounting surface on which the NAND memories 10, the drive control circuit 4, and the like are mounted. In this embodiment, the circuit board 8 is exemplified as a single-sided mounting board.

That is, the circuit board 8 is designed such that parts to be mounted thereon including the NAND memory 10 and the drive control circuit 4 are mounted on the first surface 8a, and no parts are disposed on the second surface 8b. Due to such a configuration, the semiconductor device 100 according to this embodiment may reduce a thickness thereof compared to a semiconductor device where parts are mounted on both surfaces of the circuit board 8.

Although the parts are mounted on one surface of the circuit board 8, other parts may be additionally provided on the second surface 8b of the circuit board 8 according to this embodiment. Further, test pads for checking performances of the product may be mounted on the second surface 8b of the circuit board 8. In this case, there is no limitation on high density designing of pads, which may occur when the pads are mounted in a narrow region of the first surface 8a, and the adjustment of positions of parts mounted on the first surface 8a, which may become necessary when the pads are mounted in a narrow region of the first surface 8a or the like, becomes unnecessary. Hence, the arrangement of the pads may become more flexible. Further, test pad electrodes may be disposed right behind the respective parts mounted on the first surface 8a and, hence, lengths of lines for wiring may be made short whereby it is possible to avoid an electrical loss.

The present invention is not limited to the above-described configuration. For example, the NAND memory 10 and the drive control circuit 4 may be mounted on different surfaces respectively, or the NAND memory 10 and other parts may be mounted on different surfaces respectively.

The circuit board 8 includes a first edge portion 8c and a second edge portion 8d positioned on a side opposite to the first edge portion 8c. A connector 9 is disposed on the first edge portion 8c. The connector 9 is connected to the host 1 and functions as the above-described interface 2 and the communication interface 3, and includes a plurality of connection terminals (metal terminals). The connector 9 functions as a power source input port which supplies power from the host 1 to the power source circuit 5. The connector 9 is an LIF (Low Insertion Force) connector, for example. A slit 9a is formed in the connector 9 at a position displaced from a center position of the circuit board 8 along a short length direction of the circuit board 8, and the slit is shaped to be engaged with a projection (not illustrated in FIG. 3) or the like of the host 1. Due to such a configuration, it is possible to prevent the mounting of the semiconductor device 100 in an upside down state.

The circuit board 8 has the multi-layered structure formed by laminating synthetic resin layers. With respect to the circuit board 8, a wiring pattern is formed on a surface or an inner layer of the respective layers made of synthetic resins in various shapes. The power source circuit 5, the DRAM 20, the drive control circuit 4, and the NAND memories 10 mounted on the circuit board 8 are electrically connected to each other through the wiring pattern formed on the circuit board 8.

As illustrated in FIG. 3, the power source circuit 5 and the DRAM 20 of this embodiment are disposed in the vicinity of the connector 9. In this embodiment, the drive control circuit 4 is disposed on the semiconductor device 100 at a position away from the connector 9 in the long length direction of the circuit board 8 with respect to the power source circuit 5 and the DRAM 20. Two NAND memories 10 are further disposed on the semiconductor device 100 respectively at positions away from the connector 9 in the above-described long length direction of the circuit board 8 as viewed from the drive control circuit 4. That is, the DRAM 20, the drive control circuit 4, and the two NAND memories 10 are disposed in this order along the long length direction of the circuit board 8 from a side of the connector 9. The disposition of the respective electronic parts mounted on the surface of the circuit board 8 is not limited to the above-described disposition, and the two NAND memories 10 may be disposed parallel to a short axis direction of the circuit board 8 in FIG. 3, for example.

Here, a range of “in the vicinity of” in this embodiment means an area having a distance within which one BGA (Ball Grid Array), a semiconductor part such as an LGA (Land Grid Array), or a circuit may be mounted. To be more specific, “in the vicinity of the predetermined structure” indicates a region including an area where the predetermined structure is provided and an area around the predetermined structure from an edge of the structure where approximately one another semiconductor unit may be disposed or mounted. Accordingly, for example, “in the vicinity of the connector 9” in this embodiment indicates a region which includes an area of the substrate 8 where the connector 9 is connected and an area around this area where the power source circuit 5 and the DRAM 20 are disposed.

The drive control circuit 4 includes a controller chip 42 which increases a heat generation rate thereof during an operation due to increase of an electric current when the drive control circuit 4 accesses the NAND memory 10 or the like, which is a controlled object, or due to increase of an electric current caused by increase of a signal transmission speed, for example. The drive control circuit 4 controls the whole semiconductor 100 and, hence, the rive control circuit 4 exhibits high power consumption. Accordingly, a heat generation rate of the drive control circuit 4 is large compared with other mounted units such as the NAND memories 10. Although two NAND memories 10 are disposed on the semiconductor 100 in the first embodiment, the number of the NAND memories 10 is not limited to two.

The resistance elements 12 are electrically connected to wiring patterns which connect the drive control circuit 4 and the NAND memories 10 to each other, and function as a resistor against a signal input to and output from the NAND memories 10. Each resistance element 12 is connected to a corresponding NAND memory 10. The respective resistance elements 12 are disposed in the vicinity of the corresponding NAND memories 10.

As illustrated in FIG. 4, the drive control circuit 4 includes a circuit board 41 (package circuit board), the controller chip 42, bonding wires 43, a sealing portion (molding material) 44, and a plurality of solder balls 45. The NAND memory 10 includes a circuit board 101 (package circuit boards), a plurality of semiconductor memories 102, bonding wires 103, a sealing portion (molding material) 104, and a plurality of solder balls 105.

The circuit board 8 is, for example, a printed circuit board having multi layers and includes a power source layer, a ground layer, and an inner wiring (not illustrated in FIG. 4). The circuit board 8 electrically connects the controller chip 42 and the plurality of semiconductor memories 102 to each other through the bonding wires 43, 103, the plurality of solder balls 45, 105, and the like.

As illustrated in FIG. 4, the plurality of solder balls 45, 105 are mounted on the circuit boards 41, 101 respectively. The plurality of solder balls 45, 105 are disposed in a matrix array on a second surface 41b of the circuit boards 41 and a second surface 101b of the circuit boards 101, which are opposite to first surfaces of the circuit boards 41, 101. The plurality of solder balls 45 are not necessarily disposed on the whole second surface 41b of the circuit board 41, and may be partially arranged on the second surface 41b of the circuit board 41.

The circuit board 41 and the controller chip 42 are fixed to each other with a mount film 48, the circuit board 101 and the semiconductor memory 102 are fixed to each other with a mount film 108, and the plurality of semiconductor memories 102 are fixed to each other with the mount films 108.

As described above, the drive control circuit 4 generates more heat compared to other electronic parts when the drive control circuit 4 is energized. Heat generated by the drive control circuit 4 is transferred to the circuit board 8 through the plurality of solder balls 45, and spreads in the inside of the circuit board 8 through the metal-made power source layer, the metal-made ground layer, the metal-made inner wirings, and the like of the circuit board 8. When heat generated by the drive control circuit 4 is not efficiently radiated, the heat is transferred to the circuit board 8 and other electronic parts mounted on the circuit board 8 such as the NAND memories 10.

For example, when a temperature of the circuit board 8 exceeds a temperature of the NAND memory 10 mounted in the vicinity of the drive control circuit 4 due to the heat generated by the drive control circuit 4, the heat transferred to the circuit board 8 is further transferred to the plurality of solder balls 105 and then to the plurality of semiconductor memories 102.

As described above, the circuit board 8 according to this embodiment is a printed circuit board formed of a material such as a glass epoxy resin so that the circuit board 8 may be deformed along with a temperature change. To be more specific, the circuit board 8 may be thermally expanded starting at portions which are heated to a high temperature such as a surface portion which faces the controller chip 42 and pad portions (not illustrated in the drawing) to which the solder balls 45 are joined, and such expanded portions push regions around these portions. As a result, the circuit board 8 may be distorted about the region where the drive control circuit 4 is mounted and may be formed into a warped shape. In this embodiment, the circuit board 8, the package circuit board 41 of the drive control circuit 4, and the package circuit board 101 of the NAND memory 10 have different thermal expansion coefficients respectively. Accordingly, when a stress tend to be concentrated on the solder balls fixed between the circuit board 8, the package circuit board 41, and the package circuit board 101, the solder balls may be melted or cracks or the like may be generated in the solder balls.

The performance of the NAND memory 10 changes depending on an environmental temperature. Particularly, when the NAND memory 10 is continuously driven under an environment of a high temperature, a thermal fatigue of the NAND memory 10 progresses. As a result, a storage capability may be lowered.

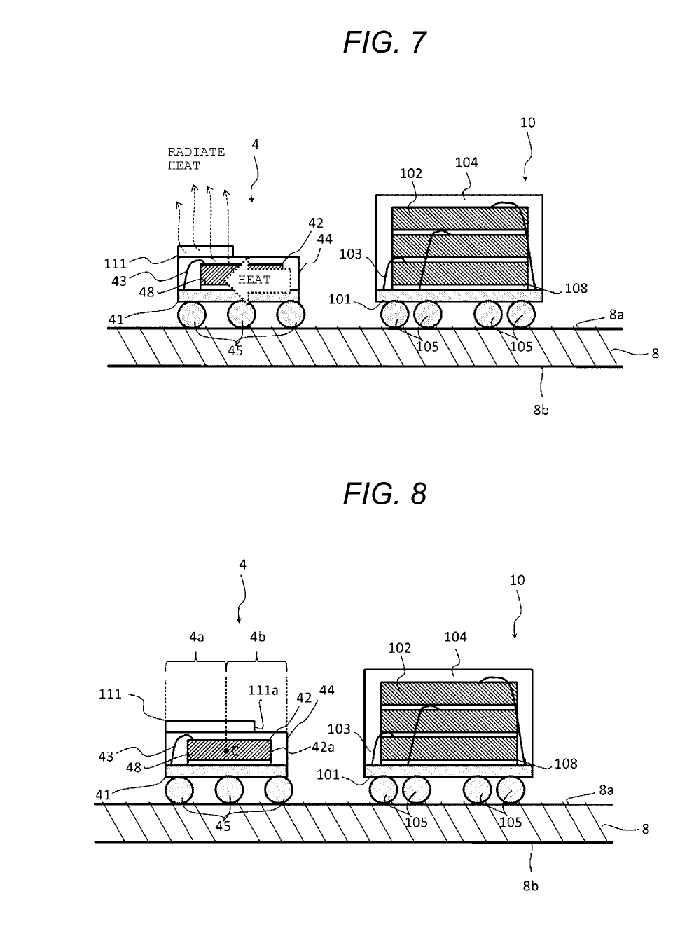

Next, configuration of a radiator of the semiconductor device 100 according to this embodiment and a flow of heat radiation are explained with reference to FIG. 5 to FIG. 7. FIG. 5 is a perspective view illustrating a heat conductive sheet of this embodiment that is laminated on the drive control circuit 4. FIG. 6 and FIG. 7 are cross-sectional views illustrating a heat radiation of the drive control circuit 4 respectively.

As illustrated in FIG. 5, the heat conductive sheet 111 is used as one example of the radiator in this embodiment. As a material of the heat conductive sheet 111, graphite is used, for example. Graphite has a structure where an excessively large planar molecule, which is referred to as a graphene sheet where benzene rings are arranged on a plane, is stacked. Accordingly, the heat conductive sheet 111 has excessively high heat transfer. Accordingly, the heat conductive sheet 111 may be formed by forming graphite into a sheet shape. The material of the heat conductive sheet used in this embodiment is not limited to graphite, and a metal plate or silicon may be also used as the material of the heat conductive sheet.

As illustrated in FIG. 5, in the drive control circuit 4 mounted on the semiconductor device 100 according to this embodiment, the heat conductive sheet 111 is laminated on a front surface of the drive control circuit 4, which is opposite to a surface facing the circuit board 8. Assuming that the drive control circuit 4 has two-split regions, that is, a first portion 4a positioned on a side of the connector 9 and a second portion 4b positioned on a side of the NAND memory 10. In this case, as illustrated in FIG. 5 to FIG. 7, the heat conductive sheet 111 is laminated on the first portion 4a which is positioned away from the NAND memories 10 with the second portion 4b disposed between the first portion 4a and the NAND memories 10.

In this embodiment, the portion of the surface of the drive control circuit 4 that is positioned on the side of the connector 9 as viewed from the center of the drive control circuit 4, is assumed as “first portion,” and the portion of the surface of the drive control circuit 4 that is positioned on the side of the NAND memory 10 is assumed as “second portion.” To be more specific, assuming that the center of the controller chip 42 matches the center of an outer profile of the package 44 of the drive control circuit 4 when the circuit board 8 is viewed from a side of a first surface 8a, “first portion” is the left half of the drive control circuit 4 positioned on the side of the connector 9 as viewed from the position of the centers. The region of the drive control circuit 4 other than “first portion,” that is, the right half of the drive control circuit 4 positioned on the side of the NAND memory 10 as viewed from the above-described centers is defined as “second portion.”

The center of the controller chip 42 may not match the center of the outer profile of the package 44 of the drive control circuit 4. The definitions of the first portion 4a and the second portion 4b are not limited to the definitions described above.

For example, when the package 44 of the drive control circuit 4 is viewed from the side of the first surface 8a of the circuit board 8, an arbitrary point P is located in a region of the package 44 excluding one side of the package 44 on the side of the connector 9 and the other side of the package 44 on a side opposite to the one side, and the region of the package 44 on the side of the connector 9 with respect to the point P may be defined as “first portion,” and the region of the package 44 on the side of the NAND memory 10 with respect to the point P may be defined as “second portion.”

The above-described point P is defined with respect to the case where the package 44 is viewed in a front view. However, the point P may be defined with respect to the case where the controller chip 42 is viewed in a front view. In such a case, a point P is defined in a region of the controller chip 42 excluding one side of the controller chip 42 on the side of the connector 9 and the other side of the controller chip 42 on a side opposite to the one side, and the region of the controller chip 42 on the side of the connector 9 with respect to the point P is defined as “first portion,” and the region of the controller chip 42 on the side of the NAND memory 10 is defined as “second portion.”

In both cases, the boundary between the first portion 4a and the second portion 4b is located away from an outer edge of the package 44 positioned on the side of the NAND memory 10 by a predetermined distance. The degree of heat radiation effect of the drive control circuit 4 changes corresponding to a length of the distance.

Hereinafter, heat radiation of the drive control circuit 4 according to this embodiment is explained with reference to FIG. 6 and FIG. 7. In this embodiment, explanation of some parts is omitted for simplifying the explanation.

As illustrated in FIG. 6, when the controller chip 42 in the drive control circuit 4 generates heat along with the operation of the semiconductor device 100 according to this embodiment, the heat generated by the controller chip 42 is transferred to the sealing portion 44, which is in contact with an outer surface of the controller chip 42, and is also transferred to the circuit board 41, which supports the controller chip 42 thereon by way of the mount film 48 respectively. Although some of heat transferred to the sealing portion 44 are radiated into a space around the drive control circuit 4, the heat is mainly transferred to the heat conductive sheet 111 having higher heat conductivity than air through the first portion 4a. Also with respect to heat transferred to the circuit board 41 from the controller chip 42, although some of the heat are radiated into a space, the heat is mainly transferred to the circuit board 8 through the solder balls 45, which is made of metal having higher heat conductivity than air.

While the heat generated by the controller chip 42 spreads concentrically about the controller chip 42 in the direction toward members adjacent to the controller chip 42, the heat is basically transferred to members having high heat conductivity. That is, heat transferred to the sealing portion 44 from the controller chip 42 is directed to the first portion 4a on which the heat conductive sheet 111 is laminated rather than the second portion 4b of the sealing portion 44, and the heat is positively radiated through the heat conductive sheet 111.

As a result, as illustrated in FIG. 7, in the sealing portion 44 of the drive control circuit 4, a gradient of temperature distribution is generated between the first portion 4a and the second portion 4b and, thereafter, energy which is directed to maintain a thermal equilibrium state is generated in the drive control circuit 4. Accordingly, the heat generated by the controller chip 42 during driving the semiconductor device 100 is transferred as a flow toward the heat conductive sheet 111 through the first portion 4a. That is, the heat generated by the controller chip 42 during the driving of the semiconductor device 100 is transferred as a flow toward a side opposite to the NAND memories 10.

Also with respect to the heat transferred to the circuit board 41 from the controller chip 42, in accordance with the heat transfer characteristic of the sealing portion 44, the closer the solder balls 45 are positioned to the NAND memories 10 side, the lower heat transfer efficiency of transferring heat to the circuit board 8 becomes. In other words, heat transfer at a portion of the solder balls 45 corresponding to the second portion 4b of the circuit board 41 is conducted such that heat is guided to a portion of the solder balls 45 corresponding to the first portion 4a. Accordingly, the heat transfer in the direction toward the circuit board 8 from the solder balls 45 disposed right below the second portion 4b may be suppressed.

As described above, in an actual operation, the heat radiated from the drive control circuit 4 is radiated not only from a front surface of the package 44 but also from the solder balls 45. However, in general, when the heat conductive sheet 111 is laminated in the above-described manner, amount of heat radiation from the heat conductive sheet 111 is larger than that from the solder balls 45 since the lamination area of the heat conductive sheet 111 is sufficiently larger than a total contact area between all solder balls 45 and the circuit board 41 in a BGA.

Also even if the heat transfer to the circuit board 8 from a rear surface side of the circuit board 41 becomes large by adopting a method other than the BGA, by laminating the heat conductive sheet 111 on a region of a front surface of the drive control circuit 4 on the side of the connector 9 as in the case of this embodiment, it is possible to acquire an advantageous effect of suppressing the heat radiation to the NAND memory 10.

As illustrated in FIG. 7, a thermal state in the package of the drive control circuit 4 according to this embodiment always returns to a thermally equilibrium state due to the above-described heat transfer action. Heat of the drive control circuit 4 is radiated by the continuous repetition of the state illustrated in FIG. 6 and the state illustrated in FIG. 7. Accordingly, the diffusion of the heat generated by the drive control circuit 4 to the NAND memory 10 is suppressed.

As has been described heretofore, the drive control circuit 4 controls writing of data into the plurality of NAND memories 10, reading of data from these NAND memories 10, and erasing of data in these NAND memories 10. When lengths of lines for connecting the drive control circuit 4 and the NAND memories 10 are long, it is difficult for the signal lines to maintain impedance and this may cause delaying of signal transmission. Accordingly, it is preferable that a distance of wiring for connecting the drive control circuit 4 and the NAND memories 10 be shorter.

There is a possibility that electronic parts such as the power source circuit 5 and the DRAM 20 are operated with accompanying noises. When these electronic parts are not mounted between the drive control circuit 4 and the NAND memories 10, it is possible to lower a possibility that a signal exchanged between the drive control circuit 4 and the NAND memories 10 catches noises and improve stability of the operation of the semiconductor device 100.

As described above, to improve stability of the operation of the semiconductor device 100, it is desirable that the drive control circuit 4 and the NAND memories 10 be disposed adjacent to each other. By providing the region where the heat conductive sheet 111 is laminated at the position on the front surface of the drive control circuit 4 away from the NAND memories 10 as in the case of this embodiment, the region of the drive control circuit 4 where heat is radiated may be intentionally limited. Accordingly, even when the drive control circuit 4 and the NAND memories 10 are disposed adjacent to each other, it is possible to suppress elevation of a temperature of the NAND memories 10, which are usually weak against heat. It is also possible to maintain stability of the operation of the semiconductor device 100.

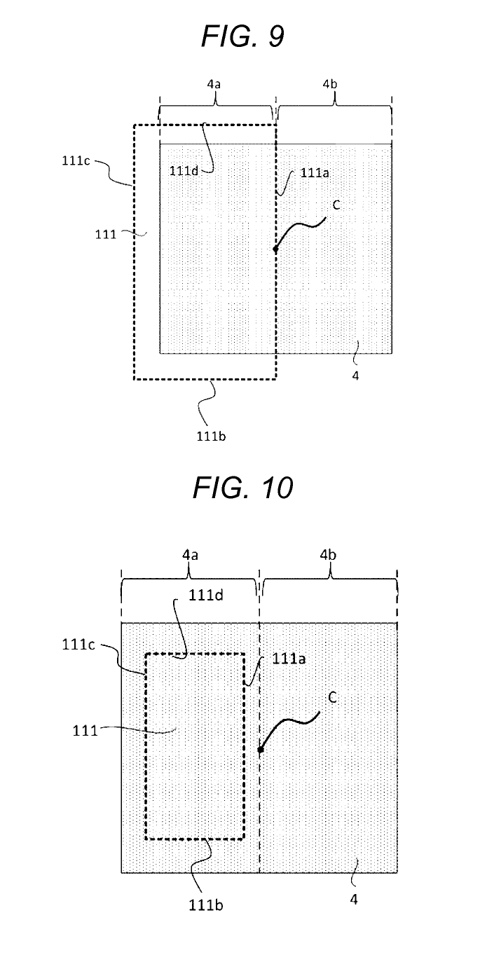

In one example of this embodiment, the heat conductive sheet 111 is laminated as illustrated in FIG. 3 to FIG. 7. However, as long as the semiconductor device 100 may achieve the above-described manner of operation by positively cooling the first portion 4a of the drive control circuit 4 compared to the second portion 4b of the drive control circuit 4, the manner of laminating the heat conductive sheet 111 is not limited to the above-described embodiment. Hereinafter, modifications of the first embodiment are explained by reference to FIG. 8 to FIG. 10. FIG. 8 is a cross sectional view illustrating a part of the semiconductor device 100 according to a first modification of the first embodiment, FIG. 9 is a plan view illustrating the drive control circuit 4 according to a second modification of the first embodiment, and FIG. 10 is a plan view illustrating the drive control circuit 4 according to a third modification of the first embodiment.

### (First Modification)

As illustrated in FIG. 8, a heat conductive sheet 111 according to the first modification is laminated such that the heat conductive sheet 111 extends from a center C of a drive control circuit 4 toward the side of the NAND memory 10, and a part of region where the heat conductive sheet 111 is laminated is a first portion 4a. To be more specific, one a side 111a of the heat conductive sheet 111 on the side of the NAND memory 10 is positioned between the center C of the above-described drive control circuit 4 and one side 42a of a controller chip 42 on the side of the NAND memory 10.

Due to such a configuration, in the same manner as the embodiment explained with reference to FIG. 3 to FIG. 7, this modification may also contribute to delaying the progress of a fatigue of the NAND memory 10 caused by heat by suppressing the heat transfer from the controller chip 42 to the side of the NAND memory 10 while radiating heat generated by the drive control circuit 4. In this modification, the example where the one side 111a of the heat conductive sheet 111 is positioned between the center C of the drive control circuit 4 and the one side 42a of the controller chip 42 is explained. However, it is sufficient that the semiconductor device 100 adopts the configuration which may suppress the heat transfer to the side of the NAND memory 10 while radiating heat generated by the drive control circuit 4. The heat conductive sheet 111 may extend to a position where the one side 111a of the heat conductive sheet 111 and the one side 42a of the controller chip 42 substantially overlap with each other when the heat conductive sheet 111 is viewed from a first surface 8a of the circuit board 8.

In this case, as the heat conductive sheet 111 is laminated closer to the side of the NAND memory 10 compared to the above-described first embodiment, an advantageous effect of suppressing the heat transfer to the NAND memory side decreases. However, a contact area between the drive control circuit 4 and the heat conductive sheet 111 is large so that heat radiation efficiency becomes high.

### (Second Modification)

As illustrated in FIG. 9, in the second modification, a heat conductive sheet 111 is laminated such that the heat conductive sheet 111 projects from a first portion 4a of a drive control circuit 4 toward a side opposite to a second portion 4b, that is, toward a connector 9 side. In other words, compared with a size of the heat conductive sheet 111 illustrated in FIG. 3 to FIG. 8, a size of the heat conductive sheet 111 according to this modification is increased toward the side of the connector 9 from an outer profile of the drive control circuit 4 (first portion 4a). Accordingly, the heat conductive sheet 111 is laminated in a state that the heat conductive sheet 111 extends outward from an outer edge portion of the first portion 4a.

As illustrated in FIG. 9, the heat conductive sheet 111 according to this modification has a rectangular shape having a first side 111a, a second side 111b, a third side 111c, and a fourth side 111d. Out of these sides, the first side 111a is disposed at a position which substantially overlaps with a center C of the drive control circuit 4 as viewed from a first surface 8a of a circuit board 8. Hence, the first side 111a according to this modification is substantially equal to the first side 111a according to the embodiment illustrated in FIG. 3 to FIG. 7. However, the second side 111b, the third side 111c, and the fourth side 111d project from outer edges of the drive control circuit 4 respectively.

Due to such a configuration, in the same manner as the embodiment illustrated in FIG. 3 to FIG. 7, this modification may also contribute to delaying fatigue of a NAND memory 10 caused by heat by suppressing the heat transfer from a controller chip 42 to the NAND memory 10 while radiating heat generated by the drive control circuit 4. In this modification, the heat conductive sheet 111 is laminated on side surfaces of the drive control circuit 4 positioned in the thickness direction of the drive control circuit and hence, heat is effectively radiated from the side surfaces of the drive control circuit 4 on the connector 9 side. Accordingly, compared to the embodiment explained by reference to FIG. 3 to FIG. 7, it is possible to direct the heat radiation direction to the direction apart from the NAND memory 10 along the extending direction of the heat conductive sheet 111. In this modification, the mode is described where all of the second side 111b, the third side 111c, and the fourth side 111d extend from outer edges of the drive control circuit 4 respectively. However, provided that the heat radiation direction may be directed in the direction different from the NAND memory 10, the embodiment is not limited to the above-described embodiment, and the heat conductive sheet 111 may have a shape where at least any one of the second side 111b, the third side 111c, and the fourth side 111d extends from the outer edge of the drive control circuit 4.

### (Third Modification)

As illustrated in FIG. 10, a heat conductive sheet 111 may have a shape smaller than a front surface of a first portion 4a of a drive control circuit 4 (a surface of the drive control circuit 4 opposite to a mounting surface which faces a circuit board 8).

Even when the heat conductive sheet 111 has such a configuration, as long as the heat conductive sheet 111 is disposed close to the first portion 4a of the drive control circuit 4, in the same manner as the embodiment illustrated in FIG. 3 to FIG. 7, it is possible to suppress the heat transfer from the controller chip 42 to the NAND memory 10 while radiating heat generated by the drive control circuit 4.

In the above-described embodiment and the plurality of modifications of the embodiment, the heat conductive sheet 111 has a rectangular shape. However, as long as the advantageous effect of this embodiment, which is that the heat transfer from the controller chip 42 to the NAND memory 10 may be prevented while radiating heat generated by the drive control circuit 4 may be acquired, the configuration is not limited to the above-described the embodiment and the modifications thereof. For example, a heat radiation gel or the like may be applied to the first portion 4a in any application form, or a heat radiation body having a shape other than a rectangular shape may be provided. Hereinafter, the explanation is made with respect to cases where a member that is different from the heat conductive sheet 111 is used for a heat radiation member.

### (Fourth Modification)

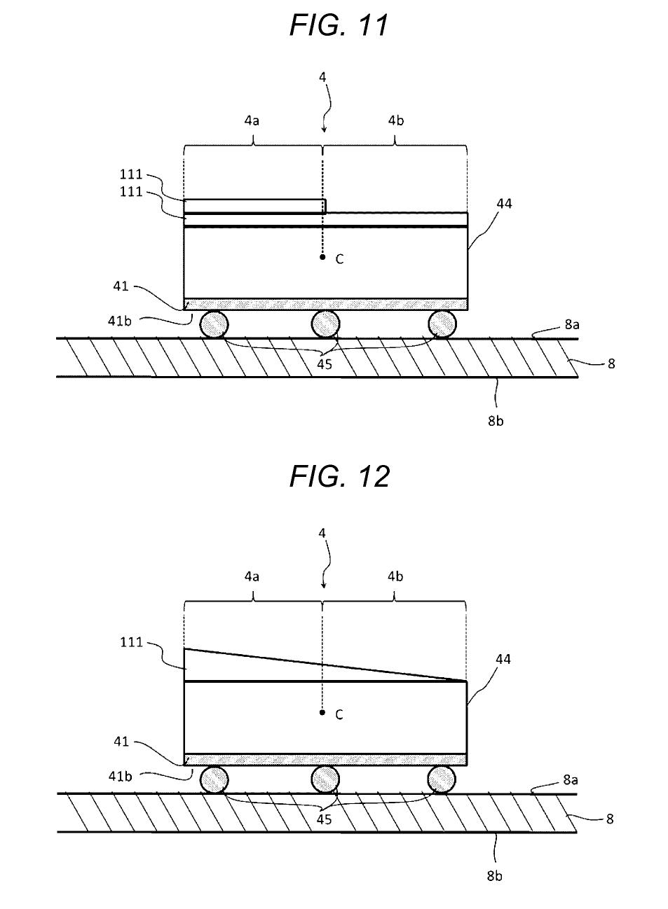

As illustrated in FIG. 11, a heat conductive sheet 111 may cover the whole front surface of a drive control circuit 4. FIG. 11 illustrates an example where one sheet of heat conductive sheet 111 is laminated on the front surface of the drive control circuit 4, and another heat conductive sheet 111 is further laminated on a connector 9 side of the heat conductive sheet 111 in an overlapped manner. Even when the semiconductor device 100 has such a configuration, heat is positively radiated through a first portion 4a where the heat conductive sheets 111 are laminated to have a larger thickness and, hence, it is possible to suppress the heat transfer from a controller chip 42 to a NAND memory 10. Further, as in the case illustrated in FIG. 12, also when one sheet of heat conductive sheet 111 has a gradient in the thickness direction thereof, it is possible to acquire the substantially same advantageous effect. For simplifying the drawing, the configuration in a package 44 is omitted in FIG. 11 and FIG. 12.

### Second Embodiment

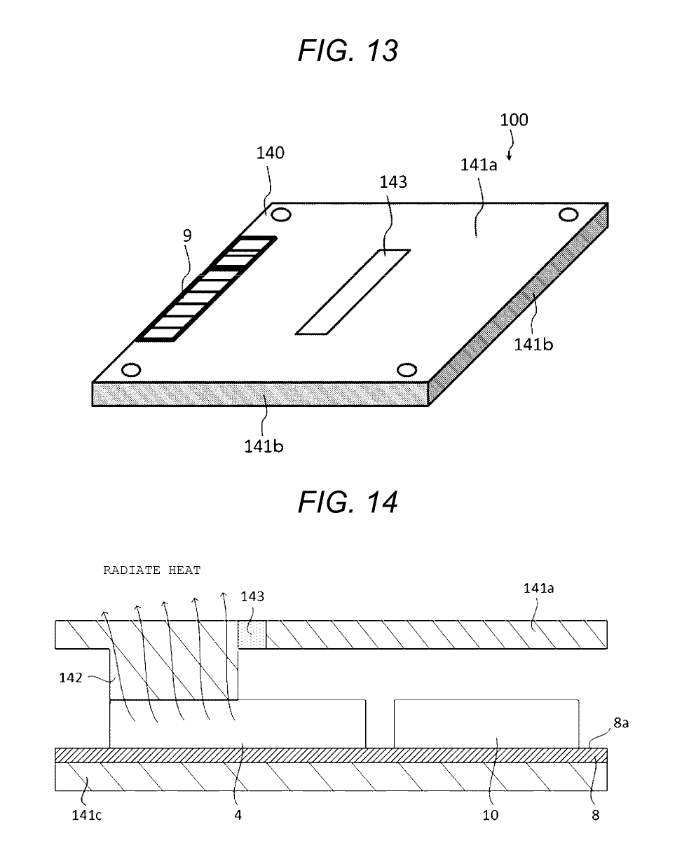

FIG. 13 is a perspective view of a semiconductor device 100 housed in a housing according to the second embodiment. FIG. 14 is a cross-sectional view of the semiconductor device 100 housed in the housing according to the second embodiment. In the explanation of the second embodiment, the configurations identical with the corresponding configurations of the first embodiment are depicted with the same symbols, and the detailed explanation of such configurations is omitted. Further, the positional relationship between a drive control circuit 4, NAND memories 10, and a DRAM 20, which are mounted on the semiconductor device 100 in the second embodiment, is also substantially equal to the positional relationship between the drive control circuit 4, the NAND memories 10, and the DRAM 20, which are mounted on the semiconductor device 100 in the first embodiment. Hence, the repeated explanation of the positional relationship is omitted.

Metal having high heat conductivity such as aluminum or copper is used for a material of a housing 141 in the second embodiment. A projecting portion 142 is formed on an upper surface 141a of the housing 141 such that the projecting portion 142 projects inwardly. The semiconductor device 100 has a structure where the projecting portion 142 is in contact only with a first portion 4a of the drive control circuit 4 in the housing 141. In this embodiment, an example where the housing 141 and the first portion 4a of the drive control circuit 4 are in direct contact with each other is shown for simplifying the explanation. However, as long as the first portion 4a of the drive control circuit 4 and the housing 141 is thermally connected to each other, the configuration is not limited to the above-described configuration, and a heat conductive member or the like may be disposed between the first portion 4a and the housing 141.

In this embodiment, the projecting portion 142 is in direct contact only with the first portion 4a of the drive control circuit 4. However, as long as the projecting portion 142 and the first portion 4a are thermally connected to each other, the configuration is not limited to the above-described configuration. For example, a heat conductive member having low rigidity such as a heat conductive sheet or heat conductive gel may be disposed between the projecting portion 142 and the first portion 4a. Further, the projecting portion 142 may be formed of such a heat conductive material. By adopting such a configuration, for example, even when the semiconductor device 100 is placed in an environment where the semiconductor device 100 easily receives an external impact, it is possible to prevent the external impact from directly transferred to the first portion 4a from the projecting portion 142. Accordingly, it is possible to reduce a pressing load applied to the drive control circuit 4. When the projecting portion 142 is formed of a heat transfer member, it is possible to prevent a shape of the housing 141 from becoming too complicated. Accordingly, a mold design for forming the housing 141 by molding may be simplified.

The housing 141 has a heat conductivity higher than air and, hence, when the housing 141 and the first portion 4a are thermally in contact with each other, heat generated by the drive control circuit 4 is transferred to the housing 141 through the first portion 4a and radiated. As a result, a gradient is generated in temperature distribution in the drive control circuit 4 so that energy which is directed to maintain a thermal equilibrium state is generated in the drive control circuit 4. Accordingly, in the same manner as the first embodiment, heat generated by the drive control circuit 4 is radiated and, at the same time, it is possible to suppress elevation of temperature of the NAND memory 10.

As illustrated in FIG. 13 and FIG. 14, a heat insulation material 143 is disposed at a portion of the upper surface 141a of the housing 141 which is above a second portion 4b and on a side of the projecting portion 142. The heat insulation material 143 suppresses the diffusion of heat transferred through the projecting portion 142 towards the NAND memory 10. Due to such a configuration, a region where the NAND memories 10 are mounted is not heated from both surfaces, that is, from the side of the circuit board 8 and the side of the housing 141a. In the same manner as the embodiment illustrated in FIG. 3 to FIG. 7, the second embodiment may also achieve the advantageous effect that a fatigue of the NAND memory 10 caused by heat can be delayed by suppressing the heat transfer from a controller chip 42 to the NAND memory 10 while radiating heat generated by the drive control circuit 4.

### Third Embodiment

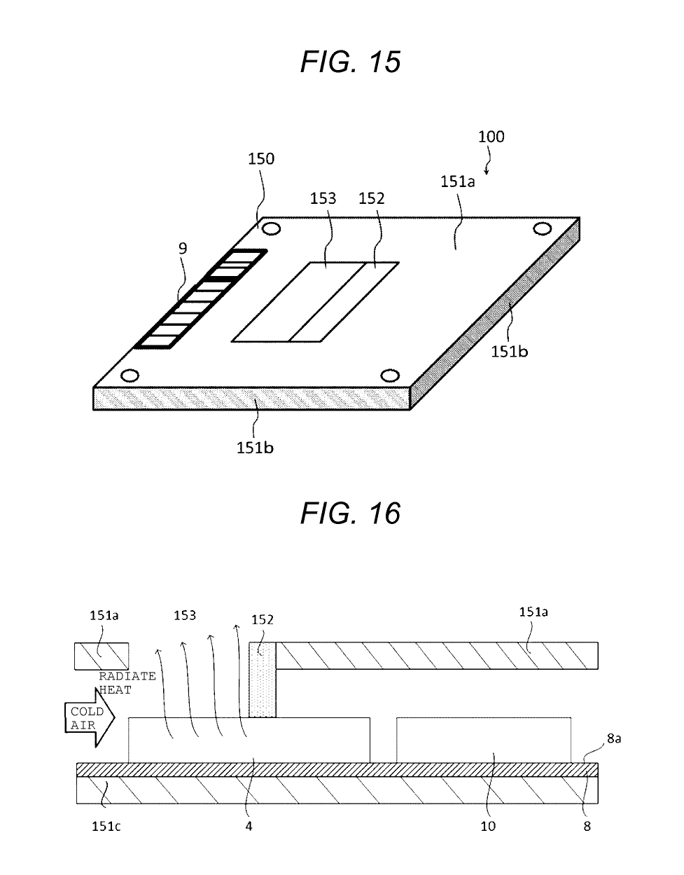

FIG. 15 is a perspective view of a semiconductor device 100 housed in a housing according to a third embodiment. FIG. 16 is a cross-sectional view of the semiconductor device 100 housed in the housing according to the third embodiment. Also in the third embodiment, the configurations corresponding to the configurations according to the above-described embodiments are given the same symbols, and the detailed explanation of such configurations is omitted. The positional relationship between the respective elements in the third embodiment is also substantially equal to the corresponding positional relationship between the respective elements in the above-described embodiments.

In the third embodiment, an opening portion 153 is formed in an upper surface 151a of a housing 151 and a wall 152 is formed on an inner side of the upper surface 151a of the housing 151. The wall 152, which is made of a heat insulation material, is in contact with a drive control circuit 4, and is positioned at a boundary between a first portion 4a and a second portion 4b of the drive control circuit 4. The opening portion 153 is formed in the upper surface 151a on a side of the first portion 4a with respect to the wall 152.

For example, outside air is supplied to the semiconductor device 100 toward the first portion 4a using a fan or the like (not illustrated in FIG. 16). In this case, heat generated by the drive control circuit 4 is radiated through the opening portion 153 through the air supplied from the fan and passing through the opening portion 153. Due to the presence of the wall 152, it is possible to suppress intrusion of air into the housing 151 from the first portion 4a. As a result, the first portion 4a of the drive control circuit 4 is effectively cooled. Even when the semiconductor device 100 does not adopt the configuration where outside air is positively supplied inside the housing 151 using the fan or the like, provided that the opening portion 153 is formed in the upper surface 151a of the housing 151, outside air and air in the housing 151 may be exchanged so that heat in the housing 151 is dissipated. Accordingly, the first portion 4a disposed in the vicinity of the opening portion 153 is more cooled than the other portions. Due to such a configuration, in the same manner as the above-described first embodiment and the second embodiment, heat is radiated from the first portion 4a. In the same manner as the embodiment explained by reference to FIG. 3 to FIG. 7, the third embodiment may also achieve the advantageous effect of delaying the progress of a fatigue of NAND memories 10 caused by heat by suppressing the heat transfer from a controller chip 42 to a NAND memory 10 while radiating heat generated by the drive control circuit 4.

### Fourth Embodiment

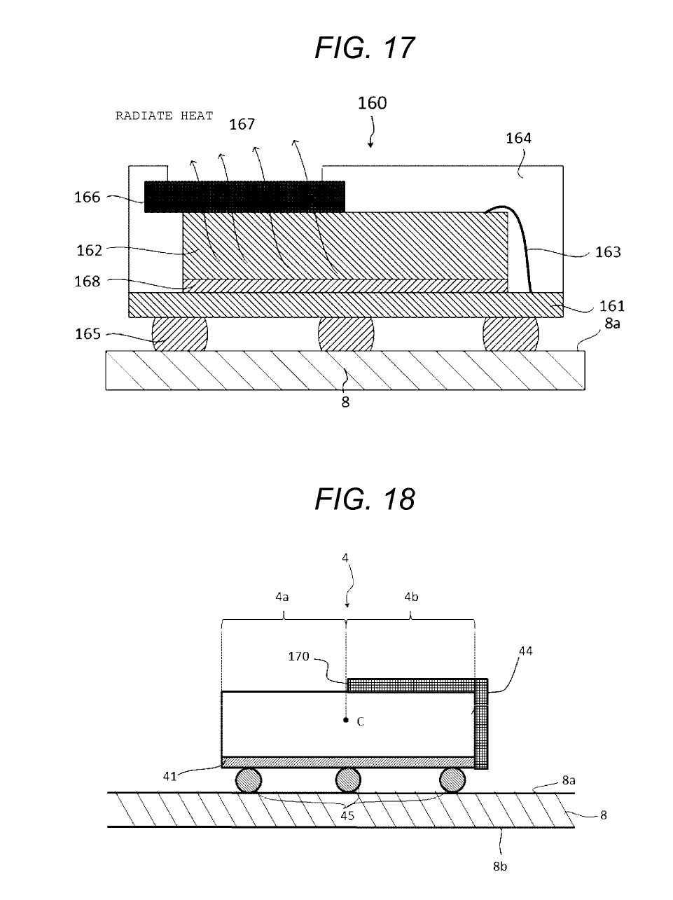

FIG. 17 is a cross-sectional view of a package as a drive control circuit 160 according to the fourth embodiment. The drive control circuit 160 includes a circuit board 161 (package circuit board), a controller chip 162, a bonding wire 163, a sealing portion (molding material) 164, a plurality of solder balls 165, and a heat conductive material 166.

In explanation of the fourth embodiment, the configurations corresponding to the configurations according to the first embodiment are given the same symbols, and the detailed explanation of such configurations is omitted. Further, the positional relationship between the drive control circuit 160, NAND memories 10, and a DRAM 20, which are mounted on a semiconductor device 100 in the fourth embodiment, is also substantially equal to the positional relationship between the corresponding elements in the first embodiment.

As illustrated in FIG. 17, the plurality of solder balls 165 is mounted on the printed circuit board 161. The plurality of solder balls 165 is disposed in a matrix array on a second surface 161b of the circuit board 161, for example. The plurality of solder balls 165 is not necessarily disposed on the whole second surface 161b of the circuit board 161, and may be partially disposed on the second surface 161b of the circuit board 161.

The drive control circuit 160 has a structure where the heat conductive material 166 is partially in contact with a front surface of the controller chip 162. Graphite, silicon, metal, or the like may be used for the heat conductive material 166, for example. The material used for the heat conductive material 166 is not limited to such materials, and the heat conductive sheet 111 used in the first embodiment may be used in this embodiment, for example.

The controller chip 162 is divided into two regions, that is, a first portion 162a positioned on a side of a DRAM 20 and a second portion 162b positioned on a side of a NAND memory 10. As illustrated in FIG. 17, the heat conductive material 166 is disposed on the side of the first portion 162a, which is a side away from the NAND memory 10.

As illustrated in FIG. 17, an opening portion 167 is formed in the sealing portion 164. Heat generated by the controller chip 162 is radiated from the opening portion 167 through the heat conductive material 166 which is in contact with the first portion 162a. In the controller chip 162, the elevation of temperature is suppressed based on the same principle applied to the above-described first to third embodiments.

### Fifth Embodiment

FIG. 18 is a cross-sectional view of a drive control circuit 4 according to the fifth embodiment. In this embodiment, a heat insulation material 170 is disposed on a second portion 4b of the drive control circuit 4. In such a configuration, heat that would be radiated in the second portion 4b is blocked by the heat insulation material 170, and is transferred to a first portion 4a and is radiated from the first portion 4a. In FIG. 18, the configuration in a package 44 is omitted for simplifying the drawing.

As described above, different from the first to fourth embodiments described heretofore, where the mechanism which positively radiates heat is provided to the first portion 4a, this embodiment adopts the configuration which blocks the heat radiation from the second portion 4b. This embodiment may, however, also acquire an advantageous effect that the heat radiation to a NAND memory 10 may be suppressed. In this case, it is necessary to provide the heat insulation material 170 such that the heat insulation material 170 covers the whole side surfaces of the package 44 and a circuit board 41 as illustrated in FIG. 18.

The heat conductivity of the solder ball 45 used in a BGA is higher than the heat conductivity of air as described above. Accordingly, there is a possibility that heat is transferred to a circuit board 8 through solder balls 45. However, an area of the first portion 4a where the heat insulation material 170 is not provided is larger than a total contact area of all solder balls 45 and, hence, it is possible to expect that the heat radiation toward the NAND memory 10 may be sufficiently suppressed.

Even when the heat transfer to the circuit board 8 from a rear surface side of the circuit board 41 becomes large by adopting methods other than the BGA, by providing the heat insulation material 170 to the second portion 4b of the drive control circuit 4 as in the case of this embodiment, it is possible to acquire an advantageous effect that the heat radiation to the NAND memory 10 may be suppressed.

### Sixth Embodiment

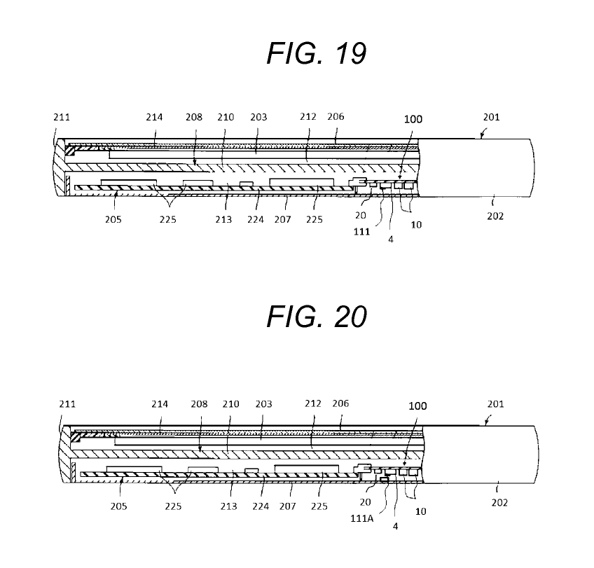

A sixth embodiment describes an example where the semiconductor device 100 explained in conjunction with the first to fifth embodiments is mounted on a computer which configures a host device. FIG. 19 illustrates a tablet portable computer 201 according to the sixth embodiment. The portable computer 201 is one example of electronic equipment, and has a size which allows a user to use the portable computer 201 while the user holds the portable computer 201 with his/her hand, for example.

The portable computer 201 includes a housing 202, a display module 203, the semiconductor device 100, and a mother board 205, as main elements. The housing 202 includes a protection plate 206, a base 207, and a frame 208. The protection plate 206 is formed of a rectangular plate made of glass or plastic, and configures a front surface of the housing 202. The base 207 is made of metal such as an aluminum alloy or a magnesium alloy, for example, and configures a bottom of the housing 202.

The frame 208 is disposed between the protection plate 206 and the base 207. The frame 208 is made of metal such as an aluminum alloy or a magnesium alloy, for example, and includes a mounting portion 210 and a bumper portion 211 as integral parts thereof. The mounting portion 210 is disposed between the protection plate 206 and the base 207. According to this embodiment, the mounting portion 210 defines a first mounting space 212 between the mounting portion 210 and the protection plate 206 and also defines a second mounting space 213 between the mounting portion 210 and the base 7.

The bumper portion 211 is integrally formed with an outer peripheral edge portion of the mounting portion 210, and continuously surrounds the first mounting space 212 and the second mounting space 213 in the circumferential direction. Further, the bumper portion 211 extends in the thickness direction of the housing 202 such that the bumper portion 211 extends between an outer peripheral edge portion of the protection plate 206 and an outer peripheral edge portion of the base 207, thus forming an outer peripheral surface of the housing 202.

The display module 203 is housed in the first mounting space 212 of the housing 202. The display module 203 is covered by the protection plate 206 and a touch panel 214 having a handwriting input function is disposed between the protection plate 206 and the display module 203. The touch panel 214 is adhered to a rear surface of the protection plate 206.

As illustrated in FIG. 19, the semiconductor device 100 includes an SSD illustrated in the first to fourth embodiments, and is housed in the second mounting space 213 of the housing 202 together with the mother board 205. The semiconductor device 100 according to this embodiment may include the housing illustrated in the second or the third embodiment. A plurality of circuit parts such as the semiconductor device 100, a printed circuit board 8, a NAND memory 10, and a controller 4 are provided.

The printed circuit board 8 is one example of a circuit board. The printed circuit board 8 has a mounting surface 8a on which a plurality of conductive patterns is formed. The circuit parts are mounted on the mounting surface 8a of the circuit board 8, and are bonded to the conductive patterns by soldering.

The mother board 205 includes a second printed circuit board 224 and a plurality of circuit parts 225 such as a semiconductor package and a chip. The second printed circuit board 224 is one example of a circuit board. The second printed circuit board 224 has a mounting surface 224a on which a plurality of conductive patterns 226 is formed. The circuit parts 225 are mounted on the mounting surface 224a of the second printed circuit board 224, and are bonded to the conductive patterns 226 by soldering.

The semiconductor device 100 illustrated in the first to fourth embodiments adopts the one-surface mounting structure. Accordingly, as in the case of this embodiment, it is possible to mount the semiconductor device 100 on the tablet portable computer 201 that is desirable to have a smaller thickness.

As illustrated in FIG. 19, a surface of the semiconductor device 100 of this embodiment on which projecting parts are not mounted is directed to a display module side. By disposing the semiconductor device 100 in such a manner, it is possible to prevent the semiconductor device 100 from being affected by heat generated by the display module. As illustrated in FIG. 19, the drive control circuit 4 and the housing 202 of the tablet portable computer 201 are spaced apart from each other in the semiconductor device 100 according to this embodiment. By disposing the drive control circuit 4 and the housing 202 in such a manner, it is possible to prevent heat from being radiated from a front surface of the tablet portable computer so that the convenience of the tablet portable computer may be enhanced.

### Seventh Embodiment

FIG. 20 is a cross-sectional view of a semiconductor device 100 according to seventh embodiment where the semiconductor device 100 explained in the sixth embodiment is mounted on a host device 201. As illustrated in FIG. 20, a surface of the semiconductor device 100 according to this embodiment on which projecting parts are not mounted is directed to a display module side. The seventh embodiment differs from the sixth embodiment with respect to a point that a drive control circuit 4 and a housing 202 of the computer 201 are thermally connected to each other through a heat conducting portion 111A in the seventh embodiment. The heat conducting portion 111A may be formed by changing a thickness of a portion of the housing 202 greater than thicknesses of other portions of the housing 202 around the portion. That is, the heat conducting portion 111A may be formed by a projecting portion of the housing 202 projecting toward an inner portion of the housing 202. The heat conducting portion 111A may be formed using a heat conductive sheet, a heat radiation gel, or a metal member which is formed as a body separate from the housing 202.

For example, when a part having a heat radiation function such as a heat discharge port is provided to the housing 202 or when it is unnecessary to take into account portability of the host device 201 during an operation such as a case where the semiconductor device 100 is disposed in a server, no problem arises even when heat is transferred to the housing 202.

In the same manner as the above-described other embodiments, the seventh embodiment may also achieve the advantageous effect of delaying fatigue of the NAND memory 10 caused by heat by suppressing the heat transfer from the controller chip 42 to the NAND memory 10 while radiating heat generated by the drive control circuit 4.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic device comprising:
a first electronic unit;
a second electronic unit disposed adjacent to the first electronic unit, the second electronic unit having a first portion and a second portion that is closer to the first electronic unit than the first portion; and
a heat radiating unit disposed such that heat generated in the second portion of the second electronic unit is directed towards the first portion of the second electronic unit and from the first portion towards an outside of the electronic device.

2. The electronic device according to claim 1, wherein
the heat radiating unit includes a heat radiating member disposed on the first portion of the second electronic unit and not on the second portion of the second electronic unit.

3. The electronic device according to claim 2, wherein
the heat radiating member has portions not disposed on the surface of the second electronic unit.

4. The electronic device according to claim 1, further comprising:
a substrate having a surface on which the first and second electronic units are disposed, wherein
the heat radiating unit is disposed on a surface of the second electronic unit that is opposite to a surface facing the substrate.

5. The electronic device according to claim 1, wherein
the heat radiating unit is integrated with a housing of the electronic device, and
the housing includes a projecting portion that is in contact with the first portion of the second electronic unit.

6. The electronic device according to claim 5, wherein
the housing further includes a heat insulating portion that is located adjacent to a portion of the housing that is above the projection portion.

7. The electronic device according to claim 1, wherein
the second electronic unit includes a heat insulating member disposed on the second portion of the second electronic unit.

8. The electronic device according to claim 1, wherein
the first electronic unit is a semiconductor memory unit, and the second electronic unit is a processor.

9. The electronic device according to claim 8, wherein
the semiconductor memory unit is a NAND-type flash memory unit.

10. The electronic device according to claim 1, wherein
the first portion is a half portion of the second electronic unit that is separated from the first electronic unit by the second portion, which is the other half portion of the second electronic unit.

11. An electronic device comprising:
a first electronic unit; and
a second electronic unit disposed adjacent to the first electronic unit, the second electronic unit having a first portion and a second portion that is closer to the first electronic unit than the first portion, and an amount of heat radiated from the second portion towards an outside of the electronic device being smaller than an amount of heat radiated from the first portion towards the outside of the electronic device.

12. The electronic device according to claim 11, wherein
the heat radiating unit is integrated with a housing of the electronic device, and the housing has an opening at a region of the housing corresponding to the first portion of the second electronic unit.

13. The electronic device according to claim 12, wherein
the heat radiating unit further includes a heat insulating member disposed between the housing and the second portion of the second electronic unit.

14. The electronic device according to claim 11, wherein
the first electronic unit is a semiconductor memory unit, and the second electronic unit is a processor.

15. The electronic device according to claim 11, wherein
the semiconductor memory unit is a NAND-type flash memory unit.

16. The electronic device according to claim 11, wherein
the first portion is a half portion of the second electronic unit that is separated from the first electronic unit by the second portion, which is the other half portion of the second electronic unit.

17. The electronic device according to claim 11, further comprising:
a substrate having a surface on which the first and second electronic units are disposed, and the first and second electronic units are electrically connected through wirings formed on the substrate.

18. An electronic device comprising:
a display unit having a display surface and a back surface that is opposite to the display surface;
a substrate having a first surface facing the back surface of the display unit and a second surface that is opposite to the first surface;
a first electronic unit disposed on the second surface of the substrate;
a second electronic unit disposed on the second surface of the substrate adjacent to the first electronic unit, the second electronic unit having a first portion and a second portion that is closer to the first electronic unit than the first portion; and
a heat radiating unit disposed such that heat generated in the second portion of the second electronic unit is directed towards the first portion of the second electronic unit and from the first portion towards an outside of the electronic device.

19. The electronic device according to claim 18, wherein
the heat radiating unit includes a heat radiating member disposed on a surface of the first portion of the second electronic unit that is opposite to a surface facing the substrate and not on the second portion of the second electronic unit.

20. The electronic device according to claim 18, further comprising:
a housing that encloses the display unit, the substrate, the first and second electronic units, and the heat radiating unit, and has a protrusion that is connected to the heat radiating member.
